(19) United States
(12) Patent Application Publication
(10) Pub. No.: US 2007/0175659 A1
(43) Pub. Date: Aug. 2, 2007

(54) Printed circuit board

(75) Inventor: Satoshi Torii, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/655,877

(22) Filed: Jan. 22, 2007

(30) Foreign Application Priority Data
Jan. 31, 2006 (JP) 2006-022138

(51) Int. Cl. H05K 1/16

(52) U.S. Cl. 174/260

(57) ABSTRACT

Disclosed herein is a printed circuit board that allows a wiring pattern to be resistant to noise while maintaining solderability even in the case where a wiring pattern is drawn out from the lower part of a QFP. A printed circuit board on which a QFP is mounted by dip soldering is provided with two separate solder flow lands formed between a front soldering land group and a rear soldering land group and a wiring pattern formed between the two separate solder flow lands, wherein the wiring pattern is a land having a width of not less than 0.3 mm, and a space between the wiring pattern and the solder flow lands is not less than 0.4 mm nor more than 0.8 mm.

The present application is based on and claims priority of Japanese patent application No. 2006-022138 filed on Jan. 31, 2006, the entire contents of which are hereby incorporated by reference.

### BACKGROUND OF THE INVENTION

1. Field of the Invention

The present invention relates to a printed circuit board, and more particularly, to a printed circuit board on which a QFP is mounted by dip soldering.

2. Description of the Related Art

IC packages vary in the number of terminals, the space between terminals, and the way to mount a package onto a printed circuit board (inserting type, surface mounting type). These IC packages include a package called QFP (Quad Flat Package), which is a surface-mount IC package and substantially a square or substantially a rectangle in shape when viewed from above. FIG. 4 is a perspective view of a QFP. FIGS. 5A, 5B and 5C are explanatory views showing the dimensions of the QFP (all dimensions in mm). The QFP 2 is provided with terminal groups 22 on four sides, each terminal group being composed of a plurality of terminals 21.

Methods for soldering the QFP include dip soldering (also referred to as flow soldering). According to the dip soldering, surface-mount components are glued on a printed circuit board, and the printed circuit board is turned upside down (the component surface facing downward), passed through a molten solder bath, and soldered.

In order to improve solderability in the dip soldering, Japanese Patent Application Laid-Open Nos. 7-45936 and 08-64917 (patent documents 1 and 2) disclose techniques in which a solder flow land is provided on a printed circuit board. The term “land” refers to a portion in a state where conductive material such as copper foil is exposed. FIG. 6 is an explanatory view showing an example of such a printed circuit board. In FIG. 6, arrow 9 indicates the dip direction, and a printed circuit board 1 travels in this direction at the time of dip soldering. Front soldering land groups 31 and rear soldering land groups 32 are lands where the terminal groups 22 of the QFP are soldered. Solder flow lands 5 are formed between the front soldering land groups 31 and the rear soldering land groups 32. Thereby, solder can be moved smoothly along the solder flow lands 5 when soldering is shifted from the front soldering land groups 31 to the rear soldering land groups 32. A solder draw land 6 is a land for drawing off solder smoothly when soldering is finished at the rear soldering land groups 32.

There are cases where a wiring pattern is drawn to the outside of the QFP from the lower part of the QFP on the surface of the printed circuit board (see FIG. 2 in Japanese Patent Application Laid-Open No. 8-204300 (patent document 3)). In the case where a wiring pattern is drawn out through the vicinity of a solder flow land, there have conventionally been used printed circuit boards where a solder flow land is separated into two parts and a wiring pattern is drawn therebetween as shown by 11a and 13a in FIG. 1 of Japanese Patent Application Laid-Open No. 5-191026 (patent document 4) for example.

FIG. 7 is an explanatory view illustrating this wiring pattern plainly. A wiring pattern 7 runs between two separate solder flow lands 5. The wiring pattern 7 is coated with resist to prevent a solder bridge between the wiring pattern 7 and a solder flow land 5. In order to have the solder flow effect of the solder flow lands 5, it is necessary to reduce the space between the solder flow lands 5. Therefore, it is necessary to reduce the width of the wiring pattern 7. In the case where the solder draw land 6 is separated into two parts and a wiring pattern is drawn therebetween, the direction of the drawn wiring pattern and the direction of flow of solder are substantially identical; therefore, such a problem does not occur.

There has been a problem that such a conventional wiring pattern as shown in patent document 4 is susceptible to noise due to the necessity to reduce the width thereof. That is, in the case where signals are transmitted through the wiring pattern, these signals are susceptible to noise, and in the case where the wiring pattern is a ground pattern, the ground potential is susceptible to noise.

### SUMMARY OF THE INVENTION

The present invention has been made in view of the foregoing, and it is an object of the invention to provide a printed circuit board that allows a wiring pattern to be resistant to noise while maintaining solderability even in the case where the wiring pattern is drawn out from the lower part of the QFP.

A first aspect of the invention relates to a printed circuit board having a front soldering land group for soldering two terminal groups embracing a front corner of a QFP (Quad Flat Package) and a rear soldering land group for soldering two terminal groups embracing a rear corner opposite to the front corner to mount the QFP by dip soldering, the front corner being a corner put forward of the QFP and the rear corner being a corner opposite to the front corner put rearward with respect to a predetermined dip direction. The printed circuit board includes two separate solder flow lands formed between the front soldering land group and the rear soldering land group; and a wiring pattern formed between the two separate solder flow lands, wherein the wiring pattern is a land having a width of not less than 0.3 mm, and a space between the wiring pattern and the solder flow lands is not less than 0.4 mm nor more than 0.8 mm.

According to the printed circuit board of the first aspect, the wiring pattern formed between the two separate solder flow lands can function as a solder flow land.

A second aspect of the invention relates to a printed circuit board having a front soldering land group for soldering two terminal groups embracing a front corner of a QFP and a rear soldering land group for soldering two terminal groups embracing a rear corner opposite to the front corner to mount the QFP by dip soldering, the front corner being a corner put forward of the QFP and the rear corner being a corner opposite to the front corner put rearward with respect to a predetermined dip direction. The printed circuit board includes two separate solder flow lands formed between the front soldering land group and the rear soldering land group; and a plurality of wiring patterns formed between the two separate solder flow lands, wherein one of the plurality of wiring patterns has a width of not less than 0.2 mm nor more than 0.25 mm and is coated with resist, a wiring pattern other than the resist-coated wiring pattern is a land having a width of not less than 0.3 mm, a space between the resist-coated wiring pattern and the adjacent lands is not less than 0.2 mm nor more than 0.25 mm, and a space between the lands is not less than 0.4 mm nor more than 0.8 mm.

According to the printed circuit board of the second aspect, in the case where a plurality of wiring patterns are drawn out, a wiring pattern formed between the two separate solder flow lands can function as a solder flow land.

A third aspect of the invention relates to a printed circuit board having a front soldering land group for soldering two terminal groups embracing a front corner of a QFP and a rear soldering land group for soldering two terminal groups embracing a rear corner opposite to the front corner to mount the QFP by dip soldering, the front corner being a corner put forward of the QFP and the rear corner being a corner opposite to the front corner put rearward with respect to a predetermined dip direction. The printed circuit board includes a wiring pattern formed between the front soldering land group and the rear soldering land group, wherein a portion of the wiring pattern being a land, a space between the land portion of the wiring pattern and the front soldering land group is not less than 0.4 mm nor more than 0.8 mm, and a space between the land portion of the wiring pattern and the rear soldering land group is not less than 0.4 mm nor more than 0.8 mm.

According to the printed circuit board of the third aspect, a portion of the wiring pattern can be used as a solder flow land.

### BRIEF DESCRIPTION OF THE DRAWINGS

In the accompanying drawings,

FIG. 1 is an explanatory view showing the vicinity of solder flow lands of a printed circuit board according to embodiment 1 of the present invention;

FIG. 2 is an explanatory view showing the vicinity of solder flow lands of a printed circuit board according to embodiment 2 of the present invention;

FIG. 3 is an explanatory view showing the vicinity of a portion, used as a solder flow land, of a wiring pattern on a printed circuit board according to embodiment 3 of the present invention;

FIG. 4 is a perspective view of a QFP;

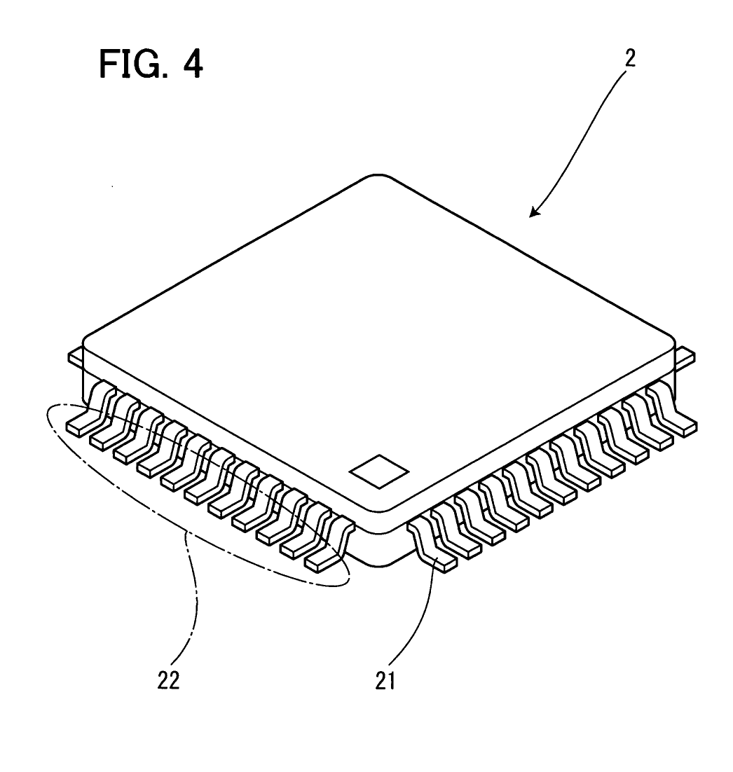

FIGS. 5A, 5B and 5C are explanatory views showing the dimensions of the QFP;

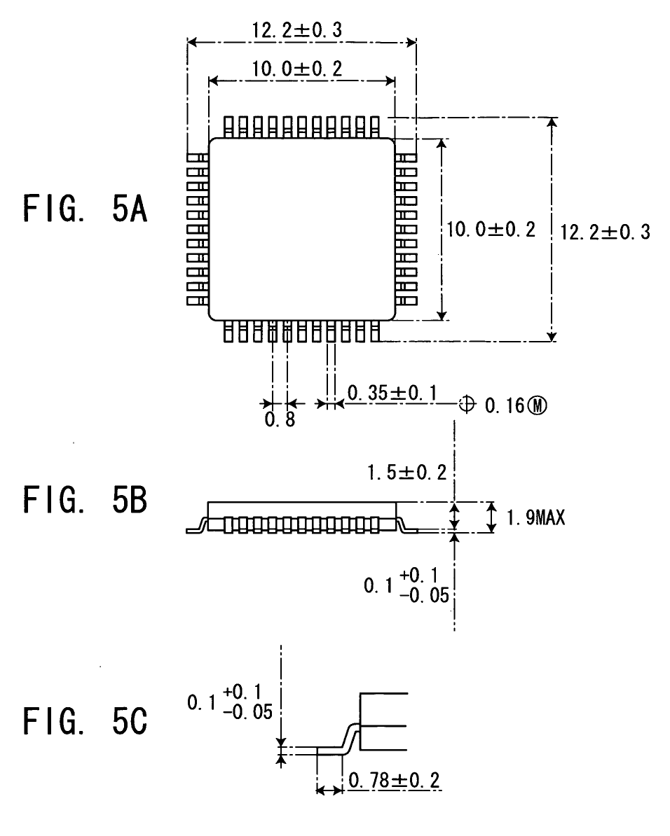

FIG. 6 is an explanatory view showing a conventional printed circuit board; and

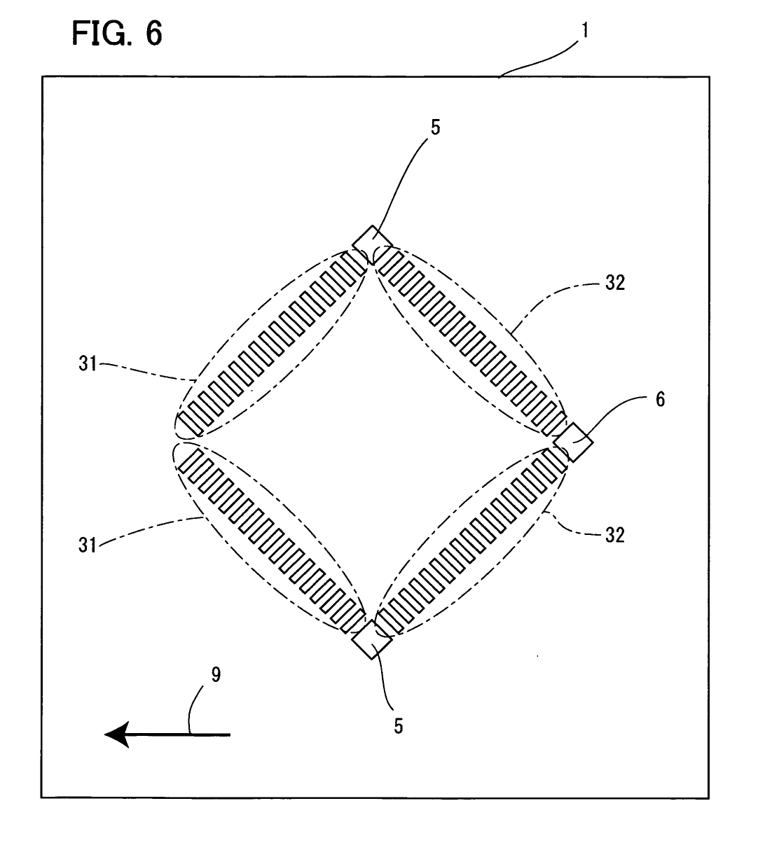

FIG. 7 is an explanatory view showing the vicinity of solder flow lands in the case where a wiring pattern is conventionally drawn out from the lower part of the QFP.

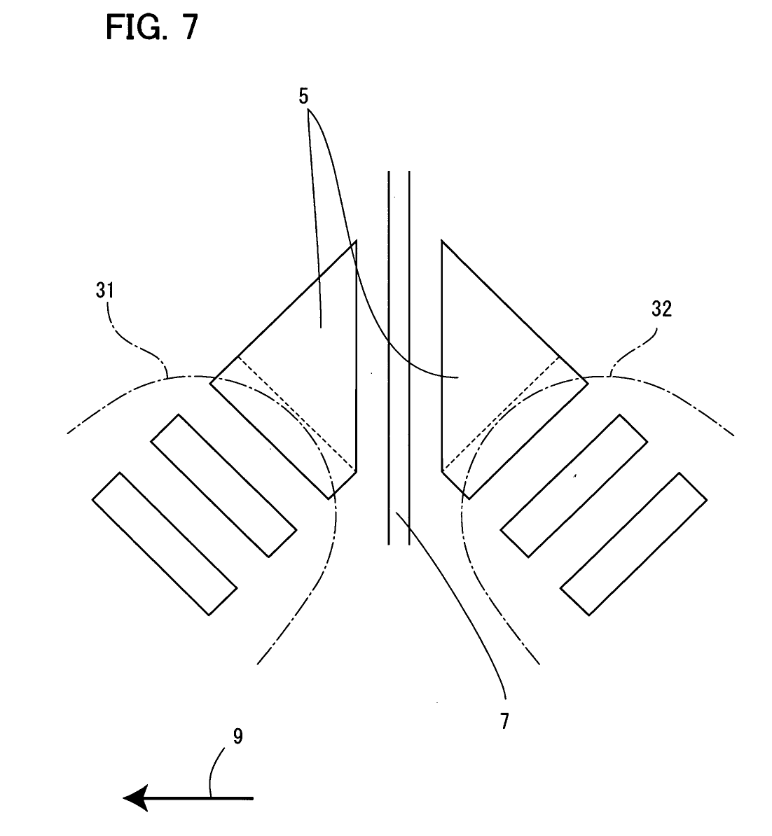

### DESCRIPTION OF THE PREFERRED EMBODIMENTS

Embodiments of the present invention will be described with reference to the accompanying drawings. The following examples are merely specific examples of the invention, and the invention is not limited thereto.

### Embodiment 1

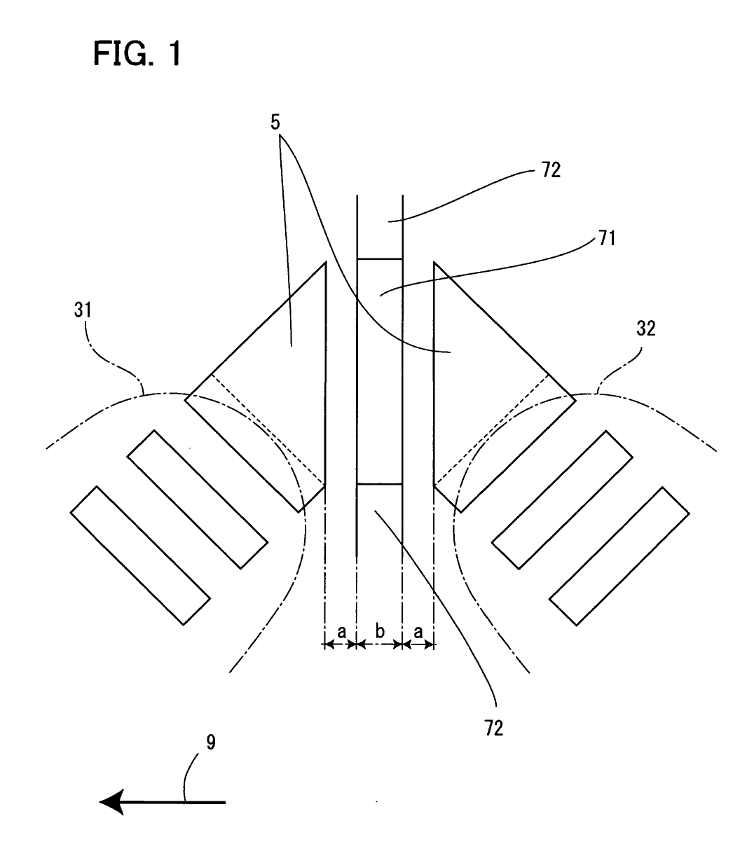

FIG. 1 is an explanatory view showing the vicinity of solder flow lands of a printed circuit board according to this example. Two separate solder flow lands 5 are formed between a front soldering land group 31 and a rear soldering land group 32. A wiring pattern runs between the two separate solder flow lands 5. The wiring pattern includes a land portion 71 and resist-coated portions 72.

The space a between the wiring pattern and the solder flow lands 5 is not less than 0.4 mm nor more than 0.8 mm, and is preferably 0.5 mm. The width b of the land portion 71 of the wiring pattern is not less than 0.3 mm, and preferably not less than 0.5 mm. These values are obtained based on conditions under which flow effect is obtained in each land and a solder bridge is avoided.

### Embodiment 2

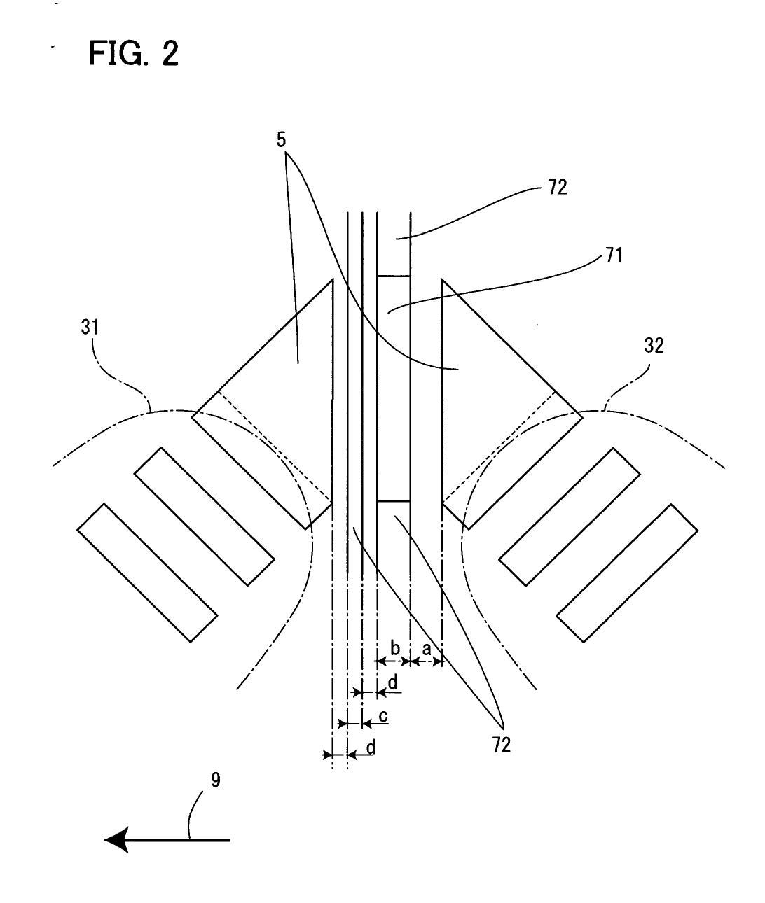

FIG. 2 is an explanatory view showing the vicinity of solder flow lands of a printed circuit board according to this example. Two separate solder flow lands 5 are formed between a front soldering land group 31 and a rear soldering land group 32. A plurality of wiring patterns run between the two separate solder flow lands 5. The plurality of wiring patterns include one wiring pattern entirely coated with resist and one or more wiring patterns having a land portion 71 and resist-coated portions 72.

The space a between the lands is not less than 0.4 mm nor more than 0.8 mm, and is preferably 0.5 mm. The width b of the land portion 71 of the wiring pattern is not less than 0.3 mm, and preferably not less than 0.5 mm. The width c of the entirely resist coated wiring pattern is not less than 0.2 mm nor more than 0.25 mm. The space d between the entirely resist coated wiring pattern and the adjacent lands is not less than 0.2 mm nor more than 0.25 mm. These values are obtained based on conditions under which flow effect is obtained in each land and a solder bridge is avoided.

### Embodiment 3

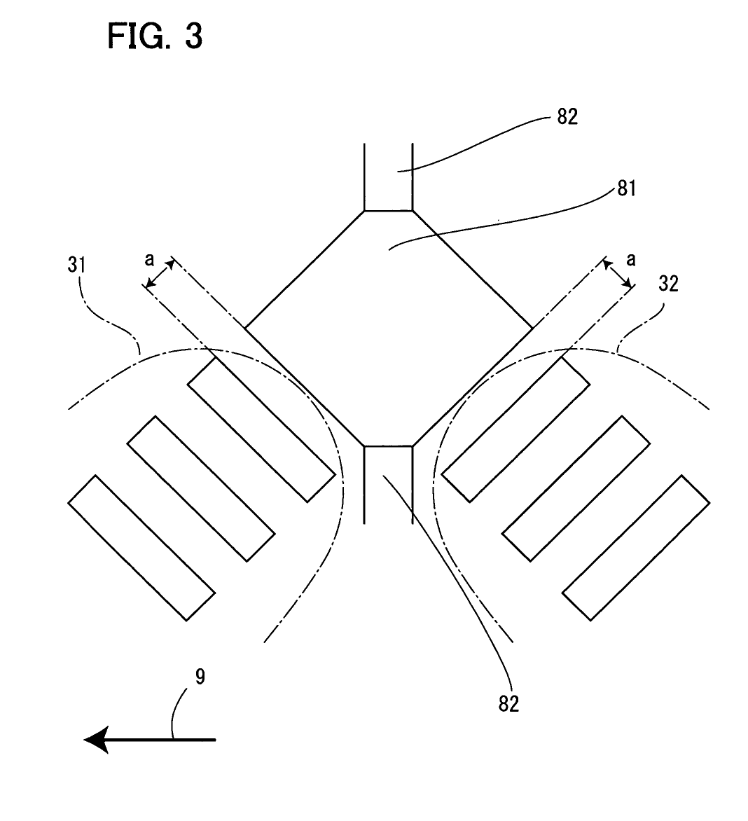

FIG. 3 is an explanatory view showing the vicinity of a portion, used as a solder flow land, of a wiring pattern on a printed circuit board according to this example. A wiring pattern is formed between a front soldering land group 31 and a rear soldering land group 32. The wiring pattern includes a land portion 81 and resist-coated portions 82.

The space a between the land portion 81 of the wiring pattern and the front soldering land group 31 (or the rear soldering land group 32) is not less than 0.4 mm nor more than 0.8 mm, and is preferably 0.5 mm. These values are obtained based on conditions under which flow effect is obtained in each land and a solder bridge is avoided.

As described above, the present invention can provide a printed circuit board that allows a wiring pattern to be resistant to noise while maintaining solderability even in the case where the wiring pattern is drawn out from the lower part of the QFP.

It should be understood by those skilled in the art that various modifications, combinations, sub-combinations and alterations may occur depending on design requirements and other factors insofar as they are within the scope of the appended claims or the equivalents thereof.

The effects of the present invention are as follows.

According to the aspects of the invention, the wiring pattern formed between the two separate solder flow lands can function as a solder flow land and have a larger width; therefore, it is possible to provide a printed circuit board that allows a wiring pattern to be resistant to noise while maintaining solderability.

Further, according to the aspects of the invention, a plurality of wiring patterns formed between the two separate solder flow lands can function as a solder flow land and have a larger width; therefore, it is possible to provide a printed circuit board that allows a wiring pattern to be resistant to noise while maintaining solderability.

Furthermore, according to the aspects of the invention, a portion of the wiring pattern can be used as a solder flow land and have a larger width; therefore, it is possible to provide a printed circuit board that allows a wiring pattern to be resistant to noise while maintaining solderability.

What is claimed is:

1. A printed circuit board having a front soldering land group for soldering two terminal groups embracing a front corner of a QFP (Quad Flat Package) and a rear soldering land group for soldering two terminal groups embracing a rear corner opposite to the front corner to mount the QFP by dip soldering, the front corner being a corner put forward of the QFP and the rear corner being a corner opposite to the front corner put rearward with respect to a predetermined dip direction, the printed circuit board comprising:
two separate solder flow lands formed between the front soldering land group and the rear soldering land group; and
a wiring pattern formed between the two separate solder flow lands,
wherein the wiring pattern is a land having a width of not less than 0.3 mm, and a space between the wiring pattern and the solder flow lands is not less than 0.4 mm nor more than 0.8 mm.

2. A printed circuit board having a front soldering land group for soldering two terminal groups embracing a front corner of a QFP and a rear soldering land group for soldering two terminal groups embracing a rear corner opposite to the front corner to mount the QFP by dip soldering, the front corner being a corner put forward of the QFP and the rear corner being a corner opposite to the front corner put rearward with respect to a predetermined dip direction, the printed circuit board comprising:
two separate solder flow lands formed between the front soldering land group and the rear soldering land group; and
a plurality of wiring patterns formed between the two separate solder flow lands,
wherein one of the plurality of wiring patterns has a width of not less than 0.2 mm nor more than 0.25 mm and is coated with resist, a wiring pattern other than the resist-coated wiring pattern is a land having a width of not less than 0.3 mm, a space between the resist-coated wiring pattern and the adjacent lands is not less than 0.2 mm nor more than 0.25 mm, and a space between the lands is not less than 0.4 mm nor more than 0.8 mm.

3. A printed circuit board having a front soldering land group for soldering two terminal groups embracing a front corner of a QFP and a rear soldering land group for soldering two terminal groups embracing a rear corner opposite to the front corner to mount the QFP by dip soldering, the front corner being a corner put forward of the QFP and the rear corner being a corner opposite to the front corner put rearward with respect to a predetermined dip direction, the printed circuit board comprising:
a wiring pattern formed between the front soldering land group and the rear soldering land group,
wherein a portion of the wiring pattern being a land, a space between the land portion of the wiring pattern and the front soldering land group is not less than 0.4 mm nor more than 0.8 mm, and a space between the land portion of the wiring pattern and the rear soldering land group is not less than 0.4 mm nor more than 0.8 mm.
